(19) United States
(12) Patent Application Publication
(10) Pub. No.: US 2022/0411340 A1
(43) Pub. Date: Dec. 29, 2022

(54) PART HAVING CORROSION-RESISTANT LAYER, MANUFACTURING PROCESS APPARATUS HAVING SAME, AND METHOD OF MANUFACTURING PART

(71) Applicant: POINT ENGINEERING CO., LTD., Chungcheongnam-do (KR)

(72) Inventors: Bum Mo AHN, Gyeonggi-do (KR); Young Heum EOM, Gyeonggi-do (KR); Tae Hwan SONG, Gyeonggi-do (KR)

(73) Assignee: POINT ENGINEERING CO., LTD., Chungcheongnam-do (KR)

(21) Appl. No.: 17/851,061

(22) Filed: Jun. 28, 2022

(30) Foreign Application Priority Data
Jun. 28, 2021 (KR) 10-2021-0083809

(51) Int. Cl. C04B 41/45; H01L 21/67; C04B 41/00; C04B 41/50; C04B 41/87; C23C 16/04; C23C 16/455; C23C 16/56

(52) U.S. Cl. CPC C04B 41/4531; H01L 21/67069; C04B 41/009; C04B 41/5031; C04B 41/5045; C04B 41/5042; C04B 41/5063; C04B 41/5059; C04B 41/5064; C04B 41/5066; C04B 41/87; C23C 16/045; C23C 16/45525; C23C 16/56; H01L 21/67098; H01L 21/67126; H01L 21/67028; H01L 21/6833

(57) ABSTRACT

Proposed are a part having a corrosion-resistant layer that minimizes peeling off and particle generation of a porous ceramic layer, a manufacturing process apparatus having the same, and a method of manufacturing the part.

### CROSS-REFERENCE TO RELATED APPLICATION

The present application claims priority to Korean Patent Application No. 10-2021-0083809, filed Jun. 28, 2021, the entire contents of which is incorporated herein for all purposes by this reference.

### BACKGROUND

### Technical Field

A chemical vapor deposition (CVD) apparatus, a physical vapor deposition (PVD) apparatus, a dry etching apparatus, etc. (hereinafter referred to as “manufacturing process apparatus”) allow the use of reactant gas, etching gas, or cleaning gas (hereinafter referred to as “process gas”) inside a manufacturing process apparatus.

In recent years, high productivity and high quality have been demanded in a deposition process. To meet this demand, efforts have been made to increase the process speed in a deposition process by increasing the RF power output of a plasma source, and to shorten the production time by using NF3 corrosive gas under high temperature conditions in a plasma cleaning process.

In the case of a part for a manufacturing process apparatus, it reacts with fluorine radicals and ions when exposed to high-temperature plasma gas and thus forms an aluminum fluoride reaction layer on the surface thereof. The aluminum fluoride reaction layer starts to vaporize at a high temperature (e.g., 450° C.), and the vaporization reaction is continuously carried out as a deposition or cleaning process is repeated. The vaporization of the aluminum fluoride reaction layer may cause a problem of increasing the corroded area of the part for the manufacturing process apparatus. The surface of the corroded part gradually becomes thinner as it is corroded, resulting in strength reduction and cracking. In addition, substances vaporized from the aluminum fluoride reaction layer are deposited and attached to an internal wall surface of a chamber because the internal wall surface has a relatively low temperature in the chamber. This deposit acts as a significant source of contamination in the form of particles. Particles generated from the aluminum fluoride reaction layer may adhere to the wafer, thereby contaminating the wafer and causing defects on the wafer. The particles also cause a reduction in the production yield of semiconductor devices.

In an effort to prevent such corrosion and particle generation problems, techniques for coating the surface of a part or member constituting a manufacturing process apparatus with a protective film using a protective film processing apparatus have been developed. For example, a porous ceramic layer may be formed by thermal spraying of yttrium oxide (Y₂O₃) or alumina (Al₂O₃). The porous ceramic layer has a sufficient thickness to advantageously maintain corrosion resistance for a long period of time.

However, because the porous ceramic layer has a porous structure and a rough surface, when the process gas through pores is highly corrosive or the porous ceramic layer is exposed to plasma for a long period of time in plasma processing, the porous ceramic layer may locally undergo peeling off, causing particle generation.

The foregoing is intended merely to aid in the understanding of the background of the present disclosure, and is not intended to mean that the present disclosure falls within the purview of the related art that is already known to those skilled in the art.

### Documents of Related Art

(Patent document 1) Korean Patent Application Publication No. 10-2007-0045369.

### SUMMARY

Accordingly, the present disclosure has been made keeping in mind the above problems occurring in the related art, and an objective of the present disclosure is to provide a part having a corrosion-resistant layer that minimizes peeling off and particle generation of a porous ceramic layer, a manufacturing process apparatus having the same, and a method of manufacturing the part.

In order to achieve the above objective, according to one aspect of the present disclosure, there is provided a method of manufacturing a part having a corrosion-resistant layer, the method including: preparing a body having a porous ceramic layer; and forming a pore corrosion-resistant layer filling a pore of the porous ceramic layer by repeatedly performing a monoatomic layer generation cycle in which a precursor gas adsorption step, an inert gas feeding step, a reactant gas adsorption and replacement step, and an inert gas feeding step are sequentially performed.

Furthermore, the method may further include polishing a surface of the porous ceramic layer so that at least a portion of the surface of the porous ceramic layer is not provided with the pore corrosion-resistant layer, after the forming of the pore corrosion-resistant layer.

Furthermore, the method may further include forming a surface corrosion-resistant layer on the surface of the porous ceramic layer by repeatedly performing the monoatomic layer generation cycle in which the precursor gas adsorption step, the inert gas feeding step, the reactant gas adsorption and replacement step, and the inert gas feeding step are sequentially performed, after the polishing of the surface of the porous ceramic layer

Furthermore, the method may further include forming a surface corrosion-resistant layer on a surface of the porous ceramic layer by repeatedly performing the monoatomic layer generation cycle in which the precursor gas adsorption step, the inert gas feeding step, the reactant gas adsorption and replacement step, and the inert gas feeding step are sequentially performed, after the forming of the pore corrosion-resistant layer.

According another aspect of the present disclosure, there is provided a part having a corrosion-resistant layer, the part including: a body; a porous ceramic layer formed on the body; and a pore corrosion-resistant layer provided inside the porous ceramic layer and filling a pore of the porous ceramic layer.

Furthermore, the part may further include a surface corrosion-resistant layer provided on a surface of the porous ceramic layer.

Furthermore, a surface of the porous ceramic layer may be planarized so that at least a portion of the surface of the porous ceramic layer is not provided with the pore corrosion-resistant layer.

Furthermore, the porous ceramic layer may be formed by thermal spraying of a thermal spray material.

Furthermore, the porous ceramic layer may include at least one of an aluminum oxide layer, an aluminum nitride layer, a silicon carbide layer, an yttrium oxide layer, a boron nitride layer, a zirconia layer, and a silicon nitride layer.

Furthermore, a length of the pore corrosion-resistant layer in a depth direction of the porous ceramic layer may be larger than a thickness of the surface corrosion-resistant layer in at least a partial area.

Furthermore, the pore may include a macropore, a mesopore, and a nanopore that have different pores sizes, and the pore corrosion-resistant layer may fill and seal at least one of the macropore, the mesopore, and the nanopore.

Furthermore, the pore corrosion-resistant layer may include at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

Furthermore, the surface corrosion-resistant layer may include at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

Furthermore, a material forming the pore corrosion-resistant layer and a material forming the surface corrosion-resistant layer may be different from each other.

Furthermore, a material forming the pore corrosion-resistant layer may be in an amorphous state.

Furthermore, the pore corrosion-resistant layer may be made of the same material as the porous ceramic layer.

Furthermore, the part may constitute at least a portion of a manufacturing process apparatus for manufacturing a semiconductor or display.

According to another aspect of the present disclosure, there is provided a manufacturing process apparatus in which a part constituting at least a portion thereof is a part having a corrosion-resistant layer, wherein the part having the corrosion-resistant layer may include: a body; a porous ceramic layer formed on the body; and a pore corrosion-resistant layer provided inside the porous ceramic layer and filling a pore of the porous ceramic layer.

Furthermore, the part having the corrosion-resistant layer may further include a surface corrosion-resistant layer provided on a surface of the porous ceramic layer.

The present disclosure can provide a part having a corrosion-resistant layer that minimizes peeling off and particle generation of a porous ceramic layer, a manufacturing process apparatus having the same, and a method of manufacturing the part.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a part having a corrosion-resistant layer according to a first embodiment of the present disclosure;

FIGS. 2A to 2C are views illustrating a method of manufacturing the part having the corrosion-resistant layer according to the first embodiment of the present disclosure;

FIG. 3 is a view illustrating a part having a corrosion-resistant layer according to a second embodiment of the present disclosure;

FIGS. 4A to 4D are views illustrating a method of manufacturing the part having the corrosion-resistant layer according to the second embodiment of the present disclosure;

FIG. 5 is a view illustrating a part having a corrosion-resistant layer according to a third embodiment of the present disclosure; and

FIGS. 6A to 6C are views illustrating a method of manufacturing the part having the corrosion-resistant layer according to the third embodiment of the present disclosure.

### DESCRIPTION OF THE EMBODIMENTS

The following description merely exemplifies the principle of the present disclosure. Thus, although not explicitly described or shown in this disclosure, various devices in which the principle of the present disclosure is implemented and which are encompassed in the concept or scope of the present disclosure can be invented by one of ordinary skill in the art. It should be appreciated that all the conditional terms enumerated herein and embodiments are clearly intended only for a better understanding of the concept of the present disclosure, and the present disclosure is not limited to the particularly described embodiments and statuses.

The forgoing objectives, advantages, and features of disclosure will become more readily apparent from the following detailed description taken in conjunction with the accompanying drawings, and accordingly, one of ordinary skill in the art may easily practice the embodiment of the present disclosure.

Embodiments are described herein with reference to sectional and/or perspective illustrations that are schematic illustrations of idealized embodiments. In the drawings, thicknesses of films and regions are exaggerated for effective description of technical contents. Variations from the shapes of the illustrations as a result, for example, of manufacturing techniques and/or tolerances, are to be expected. Thus, embodiments should not be construed as limited to the particular shapes illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise”, “include”, “have”, etc. when used herein, specify the presence of stated features, integers, steps, operations, elements, components, and/or combinations thereof but do not preclude the presence or addition of one or more other features, integers, steps, operations, elements, components, and/or combinations thereof.

Hereinafter, exemplary embodiments of the present disclosure will be described in detail with reference to the accompanying drawings. Wherever possible, the same reference numerals will be used throughout different embodiments and the description to refer to the same or like elements or parts having like functions. In addition, the configuration and operation already described in other embodiments will be omitted for convenience of the description.

For clarity of description, first to second embodiments will be separately described below. However, embodiments in which the elements of each embodiment are combined are also included in the exemplary embodiments of the present disclosure.

### First Embodiment

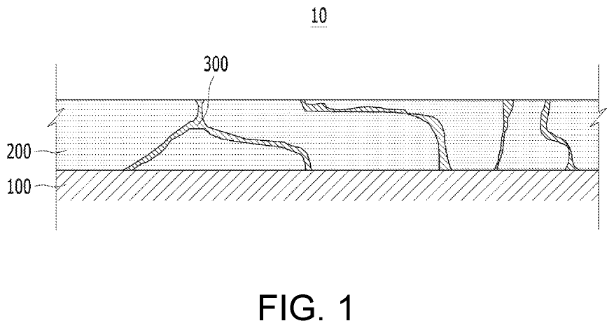

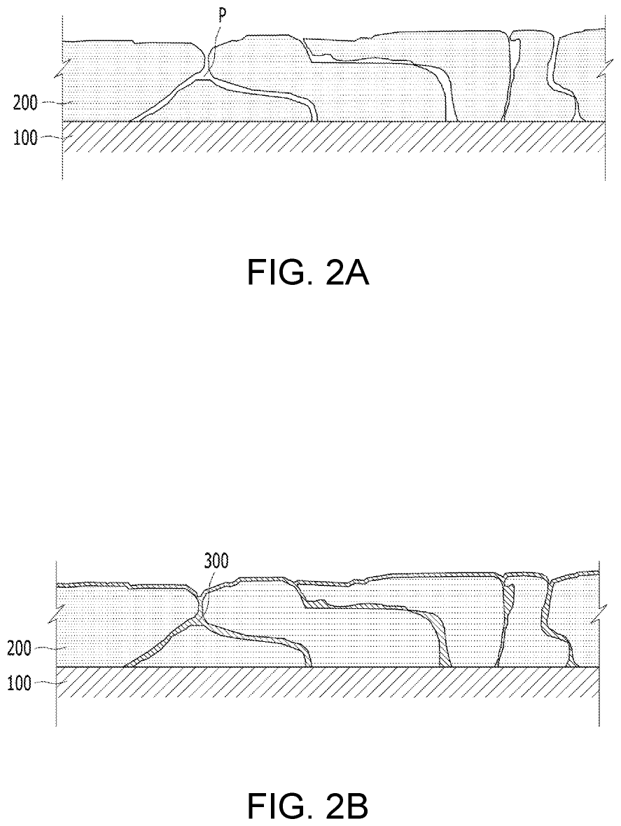

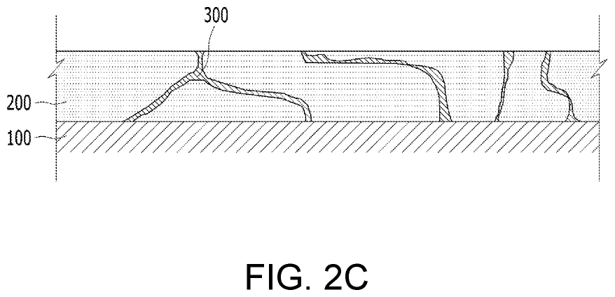

Hereinafter, a part 10 having a corrosion-resistant layer according to a first embodiment of the present disclosure will be described with reference to FIGS. 1 and 2A to 2C. FIG. 1 is a view illustrating the part 10 having the corrosion-resistant layer according to the first embodiment of the present disclosure. FIGS. 2A to 2C are views illustrating a method of manufacturing the part 10 having the corrosion-resistant layer according to the first embodiment of the present disclosure.

The part 10 having the corrosion-resistant layer according to the first embodiment of the present disclosure includes: a body 100; a porous ceramic layer 200 formed on the body 100; and a pore corrosion-resistant layer 300 provided inside the porous ceramic layer 200 and filling a pore P of the porous ceramic layer 200.

The porous ceramic layer 200 formed on at least one surface of the body 100 may be obtained by, for example, a ceramic thermal spraying method. The porous ceramic layer 200 may be formed by thermal spraying of a thermal spray material. The ceramic thermal spraying method is a technique for forming a film with a predetermined thickness on a metal or the body 100. A thermal spray material in powder form is fed into a plasma flow generated from an inert gas, heated instantaneously to a fully molten state, and accelerated toward the body 100 in the form of fine particles at a high deposition rate, followed by rapid cooling. Examples of the thermal spray material include powder, metal, non-metal, ceramic (mainly metal oxide, carbonate), cermet, and the like.

The porous ceramic layer 200 includes at least one of an aluminum oxide (Al₂O₃) layer, an aluminum nitride (AlN) layer, a silicon carbide (SiC) layer, an yttrium oxide (Y₂O₃) layer, a boron nitride (BN) layer, a zirconia (ZrO₂) layer, and a silicon nitride (Si₃N₄) layer.

Preferably, the porous ceramic layer 200 is configured as an yttrium oxide (Y₂O₃) layer, an aluminum oxide (Al₂O₃) layer, or a combination thereof. The porous ceramic layer 200 may have a porous structure including pores P. The porous ceramic layer 200 may be formed on the surface of the body 100, thereby primarily imparting corrosion resistance to the body 100.

Each of the pores P of the porous ceramic layer 200 may include a macropore, a mesopore, and a nanopore that have different pore sizes. The macropore P may have a pore size in the range of several hundred nm to several μm. The macropore P preferably has a pore size in the range of 100 nm to 1 μm. The mesopore P may have a pore size in the range of several nm to several tens of nm. The mesopore P preferably has a pore size in the range of 5 nm to 50 nm. The nanopore P may have a pore size in the range of several nm to several nm. The nanopore P preferably has a pore size in the range of 1 nm to 4 nm.

The part 100 having the corrosion-resistant layer according to the first embodiment of the present disclosure has a structure in which the pore corrosion-resistant layer 300 fills the pores P to seal the pores P. The pore corrosion-resistant layer 300 fills and seals at least one of the macropore, the mesopore, and the nanopore. With this, it is possible to block corrosive gas from penetrating to the body 100, thereby preventing the separation of the porous ceramic layer 200, and to minimize generation of particles that may act as a cause of contamination and defects of a substrate such as a wafer or glass.

The pore corrosion-resistant layer 300 may be formed by alternately feeding a precursor gas and a reactant gas. In this case, the pore corrosion-resistant layer 300 may be embodied as a variety of different types of pore corrosion-resistant layers depending on the constituent components of the precursor gas and the reactant gas.

As an example, the pore corrosion-resistant layer 300 may be formed by alternately feeding the precursor gas, which is at least one of aluminum, silicon, hafnium, zirconium, yttrium, erbium, titanium, and tantalum, and the reactant gas capable of forming the pore corrosion-resistant layer 300.

Depending on the constituent components of the precursor gas and the reactant gas, the pore corrosion-resistant layer 300 resulting from alternately feeding the precursor gas and the reactant gas may be include at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

Specifically, when the pore corrosion-resistant layer 300 is an aluminum oxide layer, the precursor gas may include at least one of aluminum alkoxide (Al(T-OC₄H₉)₃), aluminum chloride (AlCl₃), trimethyl aluminum (TMA: Al(CH₃)₃), diethylaluminum ethoxide, tris(ethylmethylamido)aluminum, aluminum sec-butoxide, aluminum tribromide, aluminum trichloride, triethylaluminum, triisobutylaluminum, trimethylaluminum, and tris(diethylamido)aluminum.

In this case, when at least one of aluminum alkoxide (Al(T-OC₄H₉)₃), diethylaluminum ethoxide, tris(ethylmethylamido)aluminum, aluminum sec-butoxide, aluminum tribromide, aluminum trichloride, triethylaluminum, triisobutylaluminum, trimethylaluminum, and tris(diethylamido)aluminum is used as the precursor gas, H₂O may be used as the reactant gas.

When aluminum chloride (AlCl₃) is used as the precursor gas, O₃ may be used as the reactant gas.

When trimethyl aluminum (TMA: Al(CH₃)₃) is used as the precursor gas, O₃ or H₂O may be used as the reactant gas.

When the pore corrosion-resistant layer 300 is an yttrium oxide layer, the precursor gas may include at least one of yttrium chloride (YCl₃), Y(C₅H₅)₃, tris(N,N-bis(trimethylsilyl)amide)yttrium(III), yttrium(III)butoxide, tris(cyclopentadienyl)yttrium(III), tris(butylcyclopentadienyl)yttrium(III), tris(2,2,6,6-tetramethyl-3,5-heptanedionato)yttrium(III), tris(cyclopentadienyl)yttrium (Cp₃Y), tris(methylcyclopentadienyl)yttrium ((CpMe)₃Y), tris(butylcyclopentadienyl)yttrium, and tris(ethylcyclopentadienyl)yttrium.

In this case, when at least one of yttrium chloride (YCl₃) and Y(C₅H₅)₃ is used as the precursor gas, O₃ may be used as the reactant gas.

When at least one of tris(N,N-bis(trimethylsilyl)amide)yttrium(III), yttrium(III)butoxide, tris(cyclopentadienyl)yttrium(III), tris(butylcyclopentadienyl)yttrium(III), tris(2,2,6,6-tetramethyl-3,5-heptanedionato)yttrium(III), tris(cyclopentadienyl)yttrium (Cp₃Y), tris(methylcyclopentadienyl)yttrium ((CpMe)₃Y), tris(butylcyclopentadienyl)yttrium, and tris(ethylcyclopentadienyl)yttrium is used as the precursor gas, at least one of H₂O, O₂, and O₃ may be used as the reactant gas.

When the pore corrosion-resistant layer 300 is a hafnium oxide layer, the precursor gas may include at least one of hafnium chloride (HfCl₄), Hf(N(CH₃)(C₂H₅))₄, Hf(N(C₂H₅)₂)₄, tetrakis(ethylmethylamido)hafnium, and pentakis(dimethylamido)tantalum.

In this case, when at least one of hafnium chloride (HfCl₄), Hf(N(CH₃)(C₂H₅))₄, and Hf(N(C₂H₅)₂)₄ is used as the precursor gas, O₃ may be used as the reactant gas.

When at least one of tetrakis(ethylmethylamido)hafnium and pentakis(dimethylamido)tantalum is used as the precursor gas, at least one of H₂O, O₂, and O₃ may be used as the reactant gas.

When the pore corrosion-resistant layer 300 is a silicon oxide layer, the precursor gas may include Si(OC₂H₅)₄. In this case, O₃ may be used as the reactant gas.

When the pore corrosion-resistant layer 300 is an erbium oxide layer, the precursor gas may include at least one of tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), tris(butylcyclopentadienyl)erbium(III), tris(2,2,6,6-tetramethyl-3,5-heptanedionato)erbium (Er(thd)₃), Er(PrCp)₃, Er(CpMe)₂, Er(BuCp)₃, and Er(thd)₃.

In this case, when at least one of tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), and tris(butylcyclopentadienyl)erbium(III) is used as the precursor gas, at least one of H₂O, O₂, and O₃ may be used as the reactant gas.

When at least one of tris(2,2,6,6-tetramethyl-3,5-heptanedionato)erbium (Er(thd)₃), Er(PrCp)₃, Er(CpMe)₂, and Er(BuCp)₃ is used the precursor gas, O₃ may be used as the reactant gas.

When Er(thd)₃ is used as the precursor gas, an O radical may be used as the reactant gas.

When the pore corrosion-resistant layer 300 is a zirconium oxide layer, the precursor gas may include at least one of zirconium tetrachloride (ZrCl₄), Zr(T-OC₄H₉)₄, zirconium(IV) bromide, tetrakis(diethylamido)zirconium(IV), tetrakis(dimethylamido)zirconium(IV), tetrakis(ethylmethylamido)zirconium(IV), tetrakis(N,N′-dimethyl-formamidinate)zirconium, tetrakis(ethylmethylamido)hafnium, pentakis(dimethylamido)tantalum, tris(dimethylamino)(cyclopentadienyl)zirconium, and tris(2,2,6,6-tetramethyl-heptane-3,5-dionate)erbium.

When at least one of these components is used as the precursor gas, at least one of H₂O, O₂, O₃, and an O radical may be used as the reactant gas.

When the pore corrosion-resistant layer 300 is a fluorinated layer, the precursor gas may include tris(2,2,6,6-tetramethyl-3,5-heptanedionato)yttrium(III). In this case, at least one of H₂O, O₂, and O₃ may be used as the reactant gas.

When the pore corrosion-resistant layer 300 is a transition metal layer, the precursor gas may include at least one of tantalum pentachloride (Tacl₅) and titanium tetrachloride (TiCl₄). In this case, an H radical may be used as the reactant gas.

Specifically, when tantalum pentachloride (Tacl₅) is used as the precursor gas and the H radical is used as the reactant gas, the transition metal layer may be a tantalum layer.

On the other hand, when titanium tetrachloride (TiCl₄) is used as the precursor gas and the H radical is used as the reactant gas, the transition metal layer may be a titanium layer.

When the pore corrosion-resistant layer 300 is a titanium nitride layer, the precursor gas may include at least one of bis(diethylamido)bis(dimethylamido)titanium(IV), tetrakis(diethylamido)titanium(IV), tetrakis(dimethylamido)titanium(IV), tetrakis(ethylmethylamido)titanium(IV), titanium(IV) bromide, titanium(IV) chloride, and titanium(IV) tert-butoxide. In this case, at least one of H₂O, O₂, O₃, and an O radical may be used as the reactant gas.

When the pore corrosion-resistant layer 300 is a tantalum nitride layer, the precursor gas may include at least one of pentakis(dimethylamido)tantalum(V), tantalum(V) chloride, tantalum(V) ethoxide, and tris(diethylamino)(tert-butylimido)tantalum(V). In this case, at least one of H₂O, O₂, O₃, and an O radical may be used as the reactant gas.

When the pore corrosion-resistant layer 300 is a zirconium nitride layer, the precursor gas may include at least one of zirconium(IV) bromide, zirconium(IV) chloride, zirconium(IV) tert-butoxide, tetrakis(diethylamido)zirconium(IV), tetrakis(dimethylamido)zirconium(IV), and tetrakis(ethylmethylamido)zirconium(IV). In this case, at least one of H₂O, O₂, O₃, and an O radical may be used as the reactant gas.

As described above, the pore corrosion-resistant layer 300 may be embodied as a variety of different types of corrosion-resistant layers depending on the constituent components of the precursor gas and the reactant gas used.

The material forming the pore corrosion-resistant layer 300 may be in an amorphous state. With this, it is possible to more effectively block penetration of corrosive gas.

The pore corrosion-resistant layer 300 may be formed by repeating a cycle (hereinafter referred to as a “monatomic layer generation cycle”) in which the precursor gas is adsorbed on the surface of the body 100, and the reactant gas is fed to generate a monoatomic layer through chemical substitution of the precursor gas with the reactant gas.

When the monoatomic layer generation cycle is performed one time, one thin monoatomic layer may be formed in the pores P. As the monoatomic layer generation cycle is repeatedly performed, a plurality of monoatomic layers may be formed. More specifically, the pore corrosion-resistant layer 300 may be formed by generating the plurality of monoatomic layers by repeatedly performing the monatomic layer generation cycle in which a precursor gas adsorption step of adsorbing the precursor gas on the surface of the body 100, a carrier gas feeding step, a reactant gas adsorption and replacement step, and a carrier gas feeding step are sequentially performed.

In the precursor gas adsorption step, a precursor adsorption layer may be formed by feeding and adsorbing the precursor gas on the surface of the body 100 using a precursor gas feeding part. One precursor adsorption layer is formed through a self-limiting reaction. Then, the carrier gas feeding step may be performed using a carrier gas feeding part. In the carrier gas feeding step, excess precursor may be removed from the precursor adsorption layer by feeding a carrier gas. In this case, an exhaust system may be operated together. The carrier gas removes excess precursor remaining in the one precursor adsorption layer formed through the self-limiting reaction. Then, the reactant gas adsorption and replacement step may be performed using a reactant gas feeding part. In the reactant gas adsorption and replacement step, the reactant gas may be fed to the precursor adsorption layer to adsorb the reactant gas on the surface of precursor adsorption layer, thereby forming the monoatomic layer through chemical substitution of the precursor adsorption layer with the reactant gas. Then, the carrier gas feeding step may be performed to remove excess reactant gas.

The monoatomic layer generation cycle may be repeated to generate the plurality of monoatomic layers. As a result, the pore corrosion-resistant layer 300 may be formed. The pore corrosion-resistant layer 300 may have improved corrosion resistance to a process gas including a reactant gas, an etching gas, or a cleaning gas used during a deposition or etching process.

When the pore corrosion-resistant layer 300 is formed using a chemical vapor deposition (CVD) method, the pore corrosion-resistant layer 300 may be formed to cover and block the top of the pores P. In this case, the inside spaces of the pores P still exist in the form of voids. Unlike this, since the pore corrosion-resistant layer 300 of the part 10 according to the first embodiment of the present disclosure is formed through the monoatomic layer generation cycle, the pore corrosion-resistant layer 300 can fully fill the pores P formed in the porous ceramic layer 200, thereby more effectively blocking penetration of corrosive gas to the body 100.

Each of the pores P formed in the porous ceramic layer 200 may be formed in a form in which the macropore P, the mesopore P, and the nanopore P are in communication with each other in the depth direction of the porous ceramic layer 200.

When a section of the pore P having the largest width corresponds to the macropore P, a surface-side pore P existing near the surface of the porous ceramic layer 200 may be the macropore P. In the case of using the CVD method, a corrosion-resistant layer may be formed in a form that blocks at least a portion of the macropore P, but may not be formed in a form that passes through the macropore P to be located in the mesopore P and the nanopore P formed under the macropore P. When the surface-side pore P is at least one of the mesopore P and the nanopore P having a width smaller than that of the macropore P, the corrosion-resistant layer may be formed to cover and block the top of the pore P, but may not be formed in the remaining pores P formed in the depth direction of the porous ceramic layer 200. Therefore, when the corrosion-resistant layer is formed using the conventional CVD method, the remaining pores P formed in the depth direction under the surface-side pore P of the porous ceramic layer 200 may exist in the form of voids. Since the corrosion-resistant layer formed in the porous ceramic layer 200 is formed to cover the top of the pores P, the corrosion-resistant layer may become thinner or cracked as it is corroded when exposed to process gas after long-term use. As a result, the inside spaces of the pores P of the porous ceramic layer 200 may be uncovered and exposed. Moisture and foreign substances existing inside the porous ceramic layer 200 are discharged to the outside through the exposed pores P, thereby causing wafer defects and a reduction in production yield.

However, the part 10 having the corrosion-resistant layer according to the first embodiment of the present disclosure may have a structure in which no voids exist therein. This may be implemented by the pore corrosion-resistant layer 300 fully filling the pores P including the inside spaces of the pores P. Specifically, since the part 10 having the corrosion-resistant layer according to the first embodiment of the present disclosure is provided with the pore corrosion-resistant layer 300 by repeatedly performing the monoatomic layer generation cycle, the pore corrosion-resistant layer 300 may be formed even in the fine-size pores P. Specifically, the pore corrosion-resistant layer 300 may be formed by generating the plurality of monoatomic layers that fully fill each of the pores P including the macropore P, the mesopore P, and the nanopore P. In the case of the part 10 having the corrosion-resistant layer according to the first embodiment of the present disclosure, since the pore corrosion-resistant layer 300 is formed through the monoatomic layer generation cycle, the pore corrosion-resistant layer 300 may be disposed to fully fill all the pores P formed in the depth direction of the porous ceramic layer 200 regardless of the size of the surface-side pore P. As a result, in the case of the part 10 having the corrosion-resistant layer according to the first embodiment of the present disclosure, the pore corrosion-resistant layer 300 may fully fill all the pores P by filling the nanopore P having the smallest width, thereby sealing the pores P. In addition, the pore corrosion-resistant layer 300 may seal the pores P by filling the mesopore P having an intermediate width between the macropore P and the nanopore P.

The length of the pore corrosion-resistant layer 300 in the depth direction of the porous ceramic layer 200 may be larger than the thickness of a surface corrosion-resistant layer 400 in at least a partial area. Since the pore corrosion-resistant layer 300 is fully formed in the pores P by repeating the monoatomic layer generation cycle, when the length of the surface-side pore P of the porous ceramic layer 200 in the depth direction thereof is relatively long, the pore corrosion-resistant layer 300 may have a length larger than the thickness of the surface corrosion-resistant layer 400 in at least a partial area of the part 10 having the corrosion-resistant layer according to the first embodiment of the present disclosure. Therefore, the part 10 having the corrosion-resistant layer according to the first embodiment of the present disclosure can block penetration of corrosive gas by the pore corrosion-resistant layer 300 fully filling the pores P even if the surface thereof is corroded.

Hereinafter, the method of manufacturing the part 10 having the corrosion-resistant layer according to the first embodiment of the present disclosure will be described with reference to FIGS. 2A to 2C.

Referring to FIG. 2A, first, a step of preparing a body 10 having a porous ceramic layer 200 is performed. The porous ceramic layer 200 formed on the body 100 may be obtained by a ceramic thermal spraying method. The porous ceramic layer 200 may be formed by thermal spraying of a thermal spray material. The ceramic thermal spraying method is a technique for forming a film with a predetermined thickness on a metal or the body 100. A thermal spray material in powder form is fed into a plasma flow generated from an inert gas, heated instantaneously to a fully molten state, and accelerated toward the body 100 in the form of fine particles at a high deposition rate, followed by rapid cooling. Examples of the thermal spray material include powder, metal, non-metal, ceramic (mainly metal oxide, carbonate), cermet, and the like. Preferably, the porous ceramic layer 200 is configured as an aluminum oxide (Al₂O₃) layer, an yttrium oxide (Y₂O₃) layer, or a combination thereof.

Next, referring to FIG. 2B, a step of forming a pore corrosion-resistant layer 300 filling pores P of the porous ceramic layer 200 is performed by repeatedly performing a monoatomic layer generation cycle in which a precursor gas adsorption step, an inert gas feeding step, a reactant gas adsorption and replacement step, and an inert gas feeding step are sequentially performed. When the monoatomic layer generation cycle is performed one time, one thin monoatomic layer may be formed in the pores P. As the monoatomic layer generation cycle is repeatedly performed, a plurality of monoatomic layers may be formed. With this, the monoatomic layers can be formed to easily penetrate between the pores P existing inside the porous ceramic layer 200. As a result of performing the monoatomic layer generation cycle multiple times, the pores P existing in the porous ceramic layer 200 are filled with the pore corrosion-resistant layer 300.

The pore corrosion-resistant layer 300 may configured as an aluminum oxide (Al₂O₃) layer or an yttrium (Y₂O₃) oxide layer. The pore corrosion-resistant layer 300 may be made of the same material as the porous ceramic layer 200 in order to improve coherency with the porous ceramic layer 200. For example, when the porous ceramic layer 200 is configured as an aluminum oxide (Al₂O₃) layer, the pore corrosion-resistant layer 300 is also configured as an aluminum oxide (Al₂O₃) layer. Alternatively, when the porous ceramic layer 200 is configured as an yttrium oxide (Y₂O₃) layer, the pore corrosion-resistant layer 300 is also configured as an yttrium oxide (Y₂O₃) layer. Meanwhile, in order to reduce manufacturing costs of the pore corrosion-resistant layer 300, the pore corrosion-resistant layer 300 may be configured as an aluminum oxide (Al₂O₃) layer.

The part 10 having the corrosion-resistant layer according to the first embodiment of the present disclosure includes the porous ceramic layer 200 configured as the aluminum oxide (Al₂O₃) layer, and the pore corrosion-resistant layer 300 configured as the aluminum oxide (Al₂O₃) layer and filling the pores P of the porous ceramic layer 200. With this, it is possible to improve corrosion resistance of the body 100 and to reduce manufacturing costs.

Next, referring to FIG. 2C, a polishing step is performed by polishing the surface of the porous ceramic layer 200 so that at least a portion of the surface of the porous ceramic layer 200 is not provided with the pore corrosion-resistant layer 300. The surface of the porous ceramic layer 200 is planarized through a polishing process so that at least the portion of the porous ceramic layer 200 is not provided with the pore corrosion-resistant layer 300. In order for the pore corrosion-resistant layer 300 to fully fill the pores P existing in the porous ceramic layer 200, the monoatomic layer generation cycle has to be repeatedly performed for a sufficient period of time. In the process of forming the pore corrosion-resistant layer 300 by repeatedly performing the monoatomic layer generation cycle, the pore corrosion-resistant layer 300 is also formed on an outer surface of the porous ceramic layer 200. The aluminum oxide (Al₂O₃) layer formed on the outer surface of the porous ceramic layer 200 is converted into aluminum fluoride (AlF₃) in a fluorine environment (HF gas or HF acid solution (or other source of fluorine) environment) as portions of the bonds to oxygen are replaced by bonds to fluorine. As the aluminum oxide (Al₂O₃) layer is converted into aluminum fluoride (AlF₃) in the fluorine environment, the mechanical properties of the aluminum oxide (Al₂O₃) layer becomes weak on the surface and it serves as a particle source. Thus, the aluminum oxide (Al₂O₃) layer formed on the surface is removed through the polishing process and prevented from serving as the particle source.

### Second Embodiment

Next, a second embodiment according to the present disclosure will be described. The embodiments described below will be mainly described in terms of characteristic elements in comparison with the first embodiment, and descriptions of the same or similar elements to the first embodiment will be omitted.

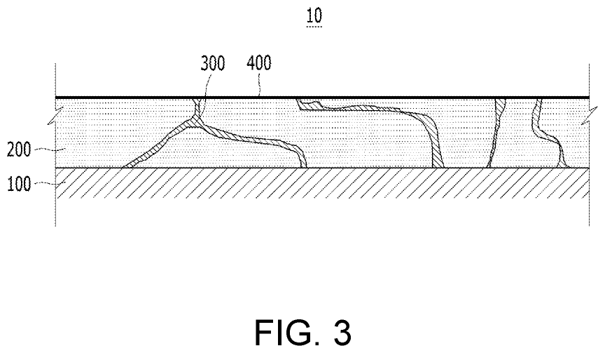

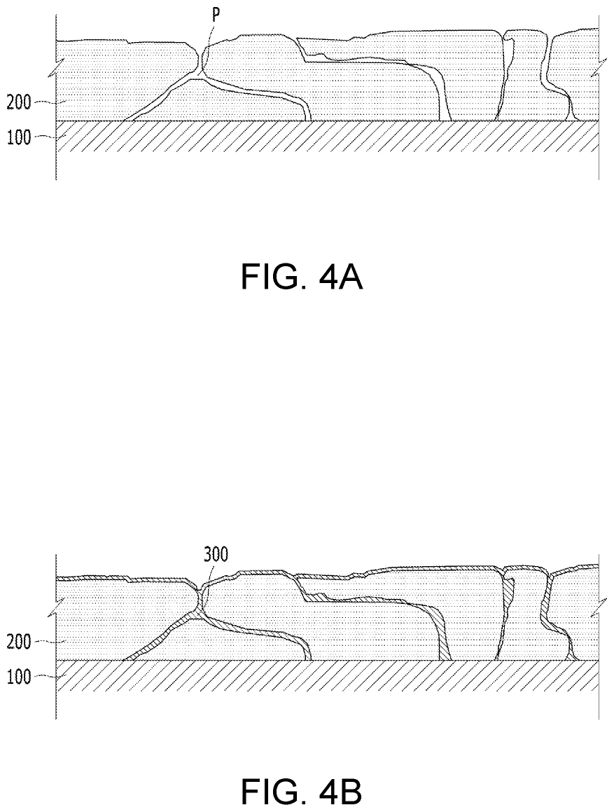

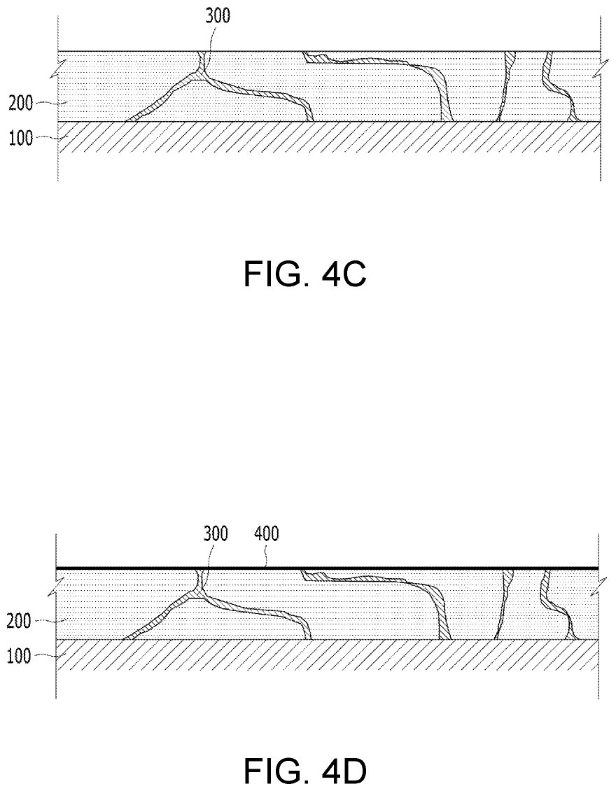

Hereinafter, a part 10 having a corrosion-resistant layer according to a second embodiment of the present disclosure will be described with reference to FIGS. 3 and 4A to 4D. FIG. 3 is a view illustrating the part 10 having the corrosion-resistant layer according to the second embodiment of the present disclosure. FIGS. 4A to 4D are views illustrating a method of manufacturing the part 10 having the corrosion-resistant layer according to the second embodiment of the present disclosure.

The part 10 having the corrosion-resistant layer according to the second embodiment of the present disclosure is different from the part 10 having the corrosion-resistant layer according to the first embodiment in that a surface corrosion-resistant layer 400 is further provided on a surface of a porous ceramic layer 200.

The surface corrosion-resistant layer 400 is formed on the surface of the porous ceramic layer 200 by repeatedly performing a monoatomic layer generation cycle in which a precursor gas adsorption step, an inert gas feeding step, a reactant gas adsorption and replacement step, and an inert gas feeding step are sequentially performed after a polishing step.

The surface corrosion-resistant layer 400 may be formed by alternately feeding a precursor gas and a reactant gas. In this case, the surface corrosion-resistant layer 400 may be embodied as a variety of different types of pore corrosion-resistant layers depending on the constituent components of the precursor gas and the reactant gas. As an example, the surface corrosion-resistant layer 400 may be formed by alternately feeding the precursor gas, which is at least one of aluminum, silicon, hafnium, zirconium, yttrium, erbium, titanium, and tantalum, and the reactant gas capable of forming the surface corrosion-resistant layer 400.

Depending on the constituent components of the precursor gas and the reactant gas, the surface corrosion-resistant layer 400 resulting from alternately feeding the precursor gas and the reactant gas may be include at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

A body 100 has primary corrosion resistance imparted by the porous ceramic layer 200 provided on a surface thereof, has secondary corrosion resistance imparted by a pore corrosion-resistant layer 300 provided in pores P of the porous ceramic layer 200, and has tertiary corrosion resistance imparted by the surface corrosion-resistant layer 400 provided on the surface of the porous ceramic layer 200. With this, it is possible to more effectively protect the body 100.

In the case of the part 10 having the corrosion-resistant layer according to the second embodiment of the present disclosure, the pore corrosion-resistant layer 300 may be configured as an aluminum oxide (Al₂O₃) layer, and the surface corrosion-resistant layer 400 may be configured as a rare earth metal-containing oxide layer. Because the amorphous aluminum oxide (Al₂O₃) has a higher temperature capability than the rare earth metal-containing oxide layer provided thereon, the aluminum oxide (Al₂O₃) is prevented from peeling off the walls of the pores P under process conditions, and is prevented from undergoing interlayer separation from the rare earth metal-containing oxide layer. The rare earth metal-containing oxide layer provides improved mechanical properties in a fluorine environment. The rare earth metal-containing oxide layer preferably includes yttrium oxide (Y₂O₃). The yttrium oxide (Y₂O₃) is converted into yttrium fluoride (YF₃) in a fluorine environment as portions of the bonds to oxygen are replaced by bonds to fluorine. In this case, even if at least a portion of the surface of yttrium oxide (Y₂O₃) is converted into yttrium fluoride (YF₃) in the fluorine environment, yttrium fluoride (YF₃) does not serve as a particle source because of excellent mechanical properties thereof. Thus, the surface corrosion-resistant layer 400 may include yttrium oxide (Y₂O₃) that is converted into yttrium fluoride (YF₃) in the fluorine environment as portions of the bonds to oxygen are replaced by bonds to fluorine.

With this, the amorphous aluminum oxide (Al₂O₃) prevents peeling of the porous ceramic layer 200 and prevents penetration of corrosive gas through the pores P under process conditions, and improved mechanical properties are provided in the fluorine environment through the surface corrosion-resistant layer 400 provided on the surface. Hereinafter, the method of manufacturing the part 10 having the corrosion-resistant layer according to the second embodiment of the present disclosure will be described with reference to FIGS. 4A to 4D.

Referring to FIG. 4A, first, a step of preparing a body 10 having a porous ceramic layer 200 is performed. The porous ceramic layer 200 formed on the body 100 may be obtained by a ceramic thermal spraying method. The porous ceramic layer 200 may be formed by thermal spraying of a thermal spray material. The ceramic thermal spraying method is a technique for forming a film with a predetermined thickness on a metal or the body 100. A thermal spray material in powder form is fed into a plasma flow generated from an inert gas, heated instantaneously to a fully molten state, and accelerated toward the body 100 in the form of fine particles at a high deposition rate, followed by rapid cooling. Examples of the thermal spray material include powder, metal, non-metal, ceramic (mainly metal oxide, carbonate), cermet, and the like.

Next, referring to FIG. 4B, a step of forming a pore corrosion-resistant layer 300 filling pores P of the porous ceramic layer 200 is performed by repeatedly performing a monoatomic layer generation cycle in which a precursor gas adsorption step, an inert gas feeding step, a reactant gas adsorption and replacement step, and an inert gas feeding step are sequentially performed.

Next, referring to FIG. 4C, a polishing step is performed by polishing the surface of the porous ceramic layer 200 so that at least a portion of the surface of the porous ceramic layer 200 is not provided with the pore corrosion-resistant layer 300.

Next, referring to FIG. 4D, a step of forming a surface corrosion-resistant layer 400 on the surface of the polished porous ceramic layer 200 is performed by repeatedly performing the monoatomic layer generation cycle in which the precursor gas adsorption step, the inert gas feeding step, the reactant gas adsorption and replacement step, and the inert gas feeding step are sequentially performed.

### Third Embodiment

Next, a third embodiment according to the present disclosure will be described. The embodiments described below will be mainly described in terms of characteristic elements in comparison with the second embodiment, and descriptions of the same or similar elements to the second embodiment will be omitted.

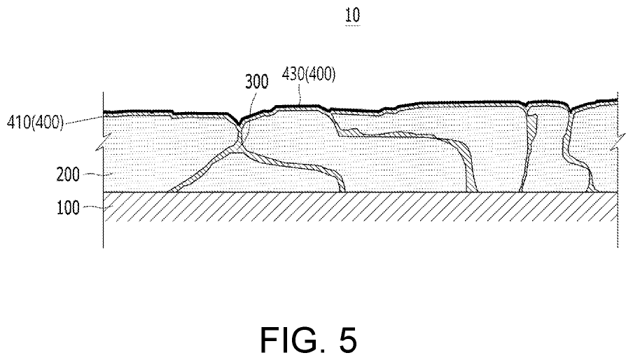

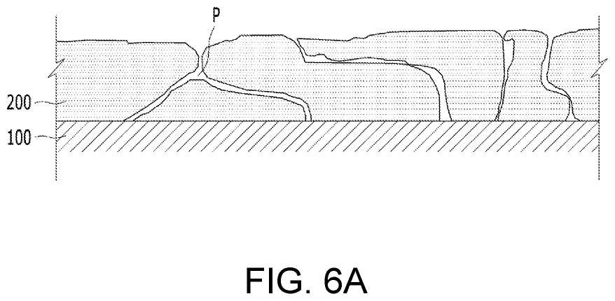

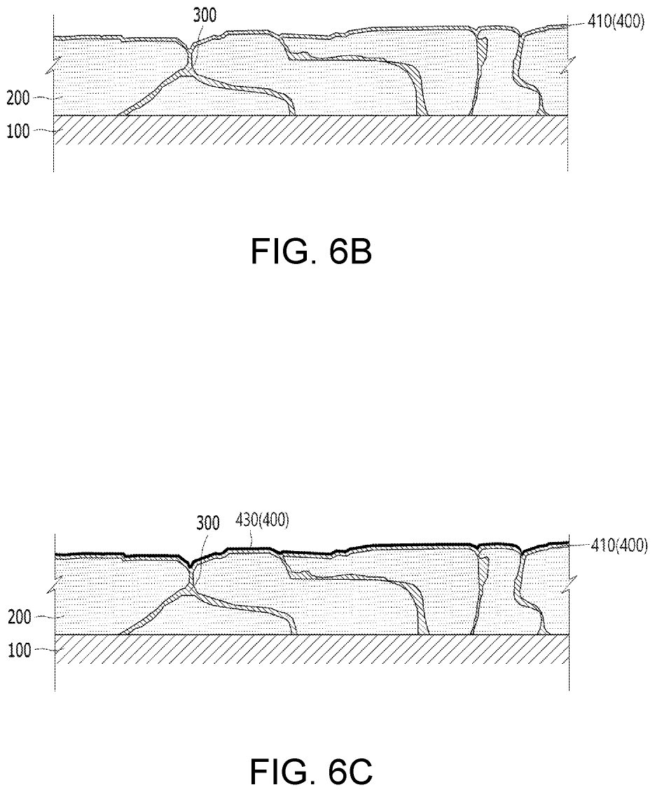

Hereinafter, a part 10 having a corrosion-resistant layer according to a third embodiment of the present disclosure will be described with reference to FIGS. 5 and 6A to 6C. FIG. 5 is a view illustrating the part 10 having the corrosion-resistant layer according to the third embodiment of the present disclosure. FIGS. 6A to 6C are views illustrating a method of manufacturing the part 10 having the corrosion-resistant layer according to the third embodiment of the present disclosure.

The part 10 having the corrosion-resistant layer according to the third embodiment of the present disclosure is different from the part 10 having the corrosion-resistant layer according to the second embodiment in that a polishing process is omitted, and a surface corrosion-resistant layer 400 is provided on a surface of a porous ceramic layer 200.

The part 10 having the corrosion-resistant layer according to the third embodiment of the present disclosure includes: a body 100; the porous ceramic layer 200 formed on the body 100; a pore corrosion-resistant layer 300 provided inside the porous ceramic layer 200 and filling pores P of the porous ceramic layer 200; a first surface corrosion-resistant layer 410 formed on the surface of the porous ceramic layer 200 and made of the same material as the pore corrosion-resistant layer 300; and a second surface corrosion-resistant layer 430 formed on a surface of the first surface corrosion-resistant layer 410.

The body 100 has primary corrosion resistance imparted by the porous ceramic layer 200 provided on a surface thereof, has secondary corrosion resistance imparted by the pore corrosion-resistant layer 300 provided in the pores P of the porous ceramic layer 200, has tertiary corrosion resistance imparted by the first surface corrosion-resistant layer 410 provided on the surface of the porous ceramic layer 200, and has quaternary corrosion resistance imparted by the second surface corrosion-resistant layer 430 provided on the surface of the first surface corrosion-resistant layer 410. With this, it is possible to more effectively protect the body 100.

The first surface corrosion-resistant layer 410 is made of the same material as the pore corrosion-resistant layer 300 and is formed together with the pore corrosion-resistant layer 300 in the process of forming the pore corrosion-resistant layer 300. By providing the first surface corrosion-resistant layer 410 of the same material as the pore corrosion-resistant layer 300, it is possible to effectively block the pore corrosion-resistant layer 300 from peeling off the walls of the pores P, and to improve adhesion of the second surface corrosion-resistant layer 430 provided thereon. In particular, it is possible to prevent cracking of the second surface corrosion-resistant layer 430 in the temperature range of 200° C. to 250° C.

The second surface corrosion-resistant layer 430 may be formed by alternately feeding a precursor gas and a reactant gas. In this case, the second surface corrosion-resistant layer 430 may be embodied as a variety of different types of pore corrosion-resistant layers depending on the constituent components of the precursor gas and the reactant gas. As an example, the second surface corrosion-resistant layer 430 may be formed by alternately feeding the precursor gas, which is at least one of aluminum, silicon, hafnium, zirconium, yttrium, erbium, titanium, and tantalum, and the reactant gas capable of forming the second surface corrosion-resistant layer 430.

Depending on the constituent components of the precursor gas and the reactant gas, the second surface corrosion-resistant layer 430 resulting from alternately feeding the precursor gas and the reactant gas may be include at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

Preferably, the first surface corrosion-resistant layer 410 consists of aluminum oxide (Al₂O₃), and the second surface corrosion-resistant layer 430 consists of yttrium oxide (Y₂O₃). The first surface corrosion-resistant layer 410 consisting of aluminum oxide (Al₂O₃) is converted into aluminum fluoride (AlF₃) in a fluorine environment (HF gas or HF acid solution (or other source of fluorine) environment) as portions of the bonds to oxygen are replaced by bonds to fluorine. As at least a portion of the surface of the first surface corrosion-resistant layer 410 consisting of aluminum oxide (Al₂O₃) is converted into aluminum fluoride (AlF₃) in the fluorine environment, the mechanical properties of the first surface corrosion-resistant layer 410 becomes weak on the surface and it serves as a particle source. The second surface corrosion-resistant layer 430 consisting of yttrium oxide (Y₂O₃) is converted into yttrium fluoride (YF₃) in a fluorine environment as portions of the bonds to oxygen are replaced by bonds to fluorine. In this case, even if at least a portion of the surface of yttrium oxide (Y₂O₃) is converted into yttrium fluoride (YF₃) in the fluorine environment, yttrium fluoride (YF₃) does not serve as a particle source because of excellent mechanical properties thereof. Thus, the second surface corrosion-resistant layer 430 may include yttrium oxide (Y₂O₃) that is converted into yttrium fluoride (YF₃) in the fluorine environment as portions of the bonds to oxygen are replaced by bonds to fluorine.

With this, the amorphous aluminum oxide (Al₂O₃) prevents peeling of the porous ceramic layer 200 and prevents penetration of corrosive gas through the pores P under process conditions, and improved mechanical properties are provided in the fluorine environment through the surface corrosion-resistant layer 400 provided on the surface.

With the configuration in which the porous ceramic layer 200, the pore corrosion-resistant layer 300, the first surface corrosion-resistant layer 410, and the second surface corrosion-resistant layer 430 are provided on the body 100, it is possible to effectively protect the body 100, thereby exhibiting the effect of increasing the operating time of the part 10. More specifically, the second surface corrosion-resistant layer 430 prevents particle generation because of excellent mechanical properties thereof in the fluorine environment. In addition, the first surface corrosion-resistant layer 410 provided under the second surface corrosion-resistant layer 430 serves as a buffer layer in a high temperature environment to suppress occurrence of cracks in the second surface corrosion-resistant layer 430. Furthermore, the porous ceramic layer 200 under the first and second surface corrosion-resistant layers 410 and 430 provides excellent corrosion resistance, and the porous corrosion-resistant layer 300 in the pores P of the porous ceramic layer 200 effectively prevents corrosive gas from penetrating to the body 100.

Hereinafter, the method of manufacturing the part 10 having the corrosion-resistant layer according to the third embodiment of the present disclosure will be described with reference to FIGS. 6A to 6C.

Referring to FIG. 6A, first, a step of preparing a body 10 having a porous ceramic layer 200 is performed. The porous ceramic layer 200 formed on the body 100 may be obtained by a ceramic thermal spraying method. The porous ceramic layer 200 may be formed by thermal spraying of a thermal spray material. The ceramic thermal spraying method is a technique for forming a film with a predetermined thickness on a metal or the body 100. A thermal spray material in powder form is fed into a plasma flow generated from an inert gas, heated instantaneously to a fully molten state, and accelerated toward the body 100 in the form of fine particles at a high deposition rate, followed by rapid cooling. Examples of the thermal spray material include powder, metal, non-metal, ceramic (mainly metal oxide, carbonate), cermet, and the like.

Next, referring to FIG. 6B, a step of forming a pore corrosion-resistant layer 300 filling pores P of the porous ceramic layer 200 is performed by repeatedly performing a monoatomic layer generation cycle in which a precursor gas adsorption step, an inert gas feeding step, a reactant gas adsorption and replacement step, and an inert gas feeding step are sequentially performed. At this time, a first surface corrosion-resistant layer 410 is formed together on a surface of the porous ceramic layer 200.

Next, referring to FIG. 6D, a step of forming a second surface corrosion-resistant layer 430 on a surface of the first surface corrosion-resistant layer 410 is performed by repeatedly performing the monoatomic layer generation cycle in which the precursor gas adsorption step, the inert gas feeding step, the reactant gas adsorption and replacement step, and the inert gas feeding step are sequentially performed.

The part 10 having the corrosion-resistant layer according to the exemplary embodiments of the present disclosure constitutes at least a portion of a manufacturing process apparatus when in use.

The manufacturing process apparatus includes a semiconductor manufacturing process apparatus and a display manufacturing process apparatus. The semiconductor manufacturing process apparatus having the part 10 having the corrosion-resistant layer includes an etching apparatus, a cleaning apparatus, a heat treatment apparatus, an ion implantation apparatus, a sputtering apparatus, a CVD apparatus, or the like. In addition, the display manufacturing process apparatus having the part 10 having the corrosion-resistant layer includes an etching apparatus, a cleaning apparatus, a heat treatment apparatus, an ion implantation apparatus, a sputtering apparatus, a CVD apparatus, or the like.

Specifically, a part for the manufacturing process apparatus may be at least one of an inner surface, a susceptor, a backing plate, a diffuser, a shadow frame, a piping line, a guard ring, and a slit valve of a manufacturing process apparatus for a deposition process. In addition, the part for the manufacturing process apparatus may be at least one of an inner surface, a lower electrode, an electrostatic chuck of the lower electrode, a baffle of the lower electrode, an upper electrode, a wall liner and a process gas exhaust unit, a piping line, a guard ring, and a slit valve of a manufacturing process apparatus for a dry etching process. However, the part for the manufacturing process apparatus is not limited thereto, and may be a part constituting at least a portion of a manufacturing process apparatus for manufacturing a semiconductor or display.

As described above, the present disclosure has been described with reference to the exemplary embodiments. However, those skilled in the art will appreciate that various modifications, additions, and substitutions are possible, without departing from the scope and spirit of the disclosure as disclosed in the accompanying claims.

What is claimed is:

1. A method of manufacturing a part having a corrosion-resistant layer, the method comprising:
preparing a body having a porous ceramic layer; and
forming a pore corrosion-resistant layer filling a pore of the porous ceramic layer by repeatedly performing a monoatomic layer generation cycle in which a precursor gas adsorption step, an inert gas feeding step, a reactant gas adsorption and replacement step, and an inert gas feeding step are sequentially performed.

2. The method of claim 1, further comprising polishing a surface of the porous ceramic layer so that at least a portion of the surface of the porous ceramic layer is not provided with the pore corrosion-resistant layer, after the forming of the pore corrosion-resistant layer.

3. The method of claim 2, further comprising forming a surface corrosion-resistant layer on the surface of the porous ceramic layer by repeatedly performing the monoatomic layer generation cycle in which the precursor gas adsorption step, the inert gas feeding step, the reactant gas adsorption and replacement step, and the inert gas feeding step are sequentially performed, after the polishing of the surface of the porous ceramic layer.

4. The method of claim 1, further comprising forming a surface corrosion-resistant layer on a surface of the porous ceramic layer by repeatedly performing the monoatomic layer generation cycle in which the precursor gas adsorption step, the inert gas feeding step, the reactant gas adsorption and replacement step, and the inert gas feeding step are sequentially performed, after the forming of the pore corrosion-resistant layer.

5. A part having a corrosion-resistant layer, the part comprising:
a body;
a porous ceramic layer formed on the body; and
a pore corrosion-resistant layer provided inside the porous ceramic layer and filling a pore of the porous ceramic layer.

6. The part of claim 5, further comprising a surface corrosion-resistant layer provided on a surface of the porous ceramic layer.

7. The part of claim 5, wherein a surface of the porous ceramic layer is planarized so that at least a portion of the surface of the porous ceramic layer is not provided with the pore corrosion-resistant layer.

8. The part of claim 5, wherein the porous ceramic layer is formed by thermal spraying of a thermal spray material.

9. The part of claim 5, wherein the porous ceramic layer includes at least one of an aluminum oxide layer, an aluminum nitride layer, a silicon carbide layer, an yttrium oxide layer, a boron nitride layer, a zirconia layer, and a silicon nitride layer.

10. The part of claim 6, wherein a length of the pore corrosion-resistant layer in a depth direction of the porous ceramic layer is larger than a thickness of the surface corrosion-resistant layer in at least a partial area.

11. The part of claim 5, wherein the pore includes a macropore, a mesopore, and a nanopore that have different pores sizes, and
the pore corrosion-resistant layer fills and seals at least one of the macropore, the mesopore, and the nanopore.

12. The part of claim 5, wherein the pore corrosion-resistant layer includes at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

13. The part of claim 6, wherein the surface corrosion-resistant layer includes at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

14. The part of claim 6, wherein a material forming the pore corrosion-resistant layer and a material forming the surface corrosion-resistant layer are different from each other.

15. The part of claim 6, wherein a material forming the pore corrosion-resistant layer is in an amorphous state.

16. The part of claim 5, wherein the pore corrosion-resistant layer is made of the same material as the porous ceramic layer.

17. The part of claim 5, wherein the part constitutes at least a portion of a manufacturing process apparatus for manufacturing a semiconductor or display.

18. A manufacturing process apparatus in which a part constituting at least a portion thereof is a part having a corrosion-resistant layer,
wherein the part having the corrosion-resistant layer comprises:
a body;
a porous ceramic layer formed on the body; and
a pore corrosion-resistant layer provided inside the porous ceramic layer and filling a pore of the porous ceramic layer.

19. The manufacturing process apparatus of claim 18, wherein the part having the corrosion-resistant layer further comprises a surface corrosion-resistant layer provided on a surface of the porous ceramic layer.
